(19) United States
(12) Patent Application Publication
(10) Pub. No.: US 2009/0032917 A1
(43) Pub. Date: Feb. 5, 2009

(54) Lead frame package apparatus and method

(75) Inventor: Ryosuke Ito, Pepperell, MA (US)

Correspondence Address: Tyco Electronics Corporation, Suite 140, 4550 New Linden Hill Road, Wilmington, DE, 19808, US

(73) Assignee: M/A-COM, Inc., Lowell, MA (US)

(21) Appl. No.: 11/888,819

(22) Filed: Aug. 2, 2007

(51) Int. Cl. H01L 23/495; H05K 3/30

(52) U.S. Cl. 257/670; 29/834; 257/E23.033

(57) ABSTRACT

The present disclosure relates to a lead frame package comprising a die attach pad and two or more electrical interconnections, wherein at least one of the two or more interconnections is affixed to the die attach pad for electrically grounding the lead frame package. The present disclosure further relates to a method for providing a lead frame package. The lead frame package comprises two or more electrical interconnections and a die attach pad. At least one electrical interconnection is affixed to the die attach pad to ground the lead frame package and at least one of the electrical interconnections is an RF signal interconnection. At least one of the die attach pad and the at least one grounding electrical interconnection is connected to a grounding contact of a circuit-board. The at least one RF signal electrical interconnection is connected to an RF signal contact on the circuit-board, thereby forming a mounted semi-conductor circuit.

### FIELD OF THE INVENTION

The present invention relates generally to lead frame packages, and more particularly to a method and apparatus for providing a package structure for use in lead frame packages.

### BACKGROUND OF THE INVENTION

The microelectronic industry has been making a tremendous improvement toward miniaturization of circuitry with greater performance. Similarly, the semiconductor industry particularly with regard to lead frame packages, has been aggressively making efforts to follow the microelectronic trend. Dies are decreasing in size, while increasing in performance. There are however, a number of disadvantages associated with conventional lead frame packages. One such disadvantage is that conventional lead frame packages are not optimized for use in frequencies greater than 10 GHz. At these frequencies, undesirable crosstalk between package interconnects may occur.

An exemplary conventional lead frame package 100 is shown in FIG. 1. The lead frame package 100 includes a die attach pad 110 positioned at the center of the lead frame package 100. The die attach pad 110 is used as platform for supporting a semiconductor die (not shown). The die attach pad 110 is affixed to the lead frame package 100 via tie bars 111a-d. The lead frame package 100 also includes a plurality of densely populated electrical interconnections 130a-130p.

The densely populated electrical interconnections 130a-p lack isolation between adjacent interconnections. This lack of isolation may cause undesirable crosstalk between signal interconnections and their adjacent interconnections. To illustrate, if the lead frame package 100 were 3 mm×3 mm, wherein interconnection 130a was an RF signal interconnection and the adjacent interconnection 130b was an intermediate frequency (IF) signal interconnection, the RF interconnection 130a and the IF interconnection 130b may be as close as 0.5 mm, thus lacking a significant amount of isolation between them. As a result, when an RF signal is applied to the RF signal interconnection 130a and an IF signal is applied to the IF signal interconnection 130b, the RF signal and the IF signal may leak into one another, resulting in corruption of both signals.

Another disadvantage associated with conventional lead frame packages relates to their manufacturing. As will be recognized by those skilled in the art, conventional methods of manufacturing require that die attach pads be tied to a perimeter of their respective lead frame packages. Typically, a die attach pad is tied to a perimeter of a lead frame package via tie bars which extend from the package's die attach pad to the corners of the package. This method of manufacturing is desirable because of its cost effectiveness. Referring again to FIG. 1, the die attach pad 110 is shown connected to the perimeter of the lead frame package 100 via the tie bars 111a-d. A problem associated with this method of manufacture, however, is that when lead frame packages are mounted onto a circuit-board, the tie bars of the die attach pad are not electrically grounded. As a result, when a signal is applied to the package, the tie bars may resonate, causing corruption and degradation of the electrical performance of the mounted semiconductor circuit.

Accordingly, it is desirable to have a lead frame package that can be manufactured utilizing conventional manufacturing technology, yet minimizes the degradation of electrical performance of mounted semiconductor circuits. It is also desirable to have a lead frame package for minimizing crosstalk between adjacent electrical interconnections within the lead frame package.

### SUMMARY OF THE INVENTION

The present disclosure relates to a lead frame package comprising a die attach pad and two or more electrical interconnections, wherein at least one of the two or more interconnections is affixed to the die attach pad for electrically grounding the lead frame package.

The present disclosure further relates to a method for providing a lead frame package. The lead frame package comprises two or more electrical interconnections and a die attach pad. At least one electrical interconnection is affixed to the die attach pad to ground the lead frame package and at least one of the electrical interconnections is an RF signal interconnection. At least one of the die attach pad and the at least one grounding electrical interconnection is connected to a grounding contact of a circuit-board. The at least one RF signal electrical interconnection is connected to an RF signal contact on the circuit-board, thereby forming a mounted semi-conductor circuit.

### BRIEF DESCRIPTION OF THE DRAWINGS

FIG. 1 illustrates a top view of a conventional lead frame package.

FIG. 2A is a perspective bottom view of a lead frame package in accordance with exemplary embodiments of the present invention.

FIG. 2B is a view of the top side of a lead frame package used in accordance with embodiments of the present invention.

FIG. 2C is a view the bottom side of an exemplary lead frame package used, in accordance with embodiments of the present invention.

FIG. 3 is an exemplary implementation of the lead frame package of FIGS. 2A-2B in accordance with the present invention.

FIG. 4 is a block diagram of an exemplary method of manufacturing lead frame packages used, in accordance with embodiments of the present disclosure.

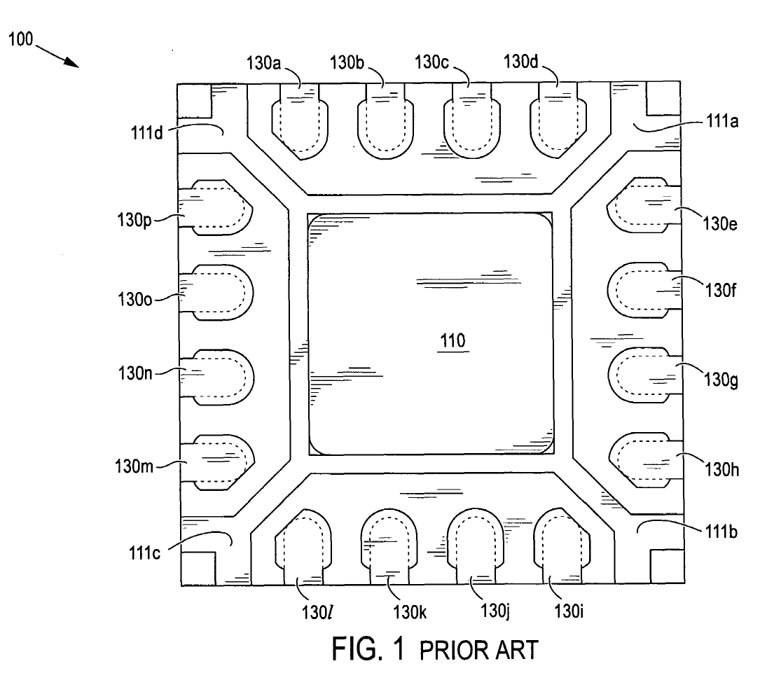

### DETAILED DESCRIPTION OF THE PREFERRED EMBODIMENTS

Described herein are methods and apparatus related to a novel lead frame package. A ‘mounted semiconductor circuit’, as the phrase is used herein, refers to a lead frame package mounted on a circuit-board. Unlike existing lead frame packages, the methods and apparatus described herein provide for a lead frame package that minimizes the degradation of electrical performance of mounted semiconductor circuits, and minimizes crosstalk between adjacent electrical interconnections. To that end, the methods and apparatus of the present disclosure are described below with reference to exemplary embodiments and figures. It should be understood, however, that these exemplary embodiments and figures are provided to illustrate and cover to facilitate an understanding of the concepts relevant to the present disclosure and as such, should not be interpreted as limiting.

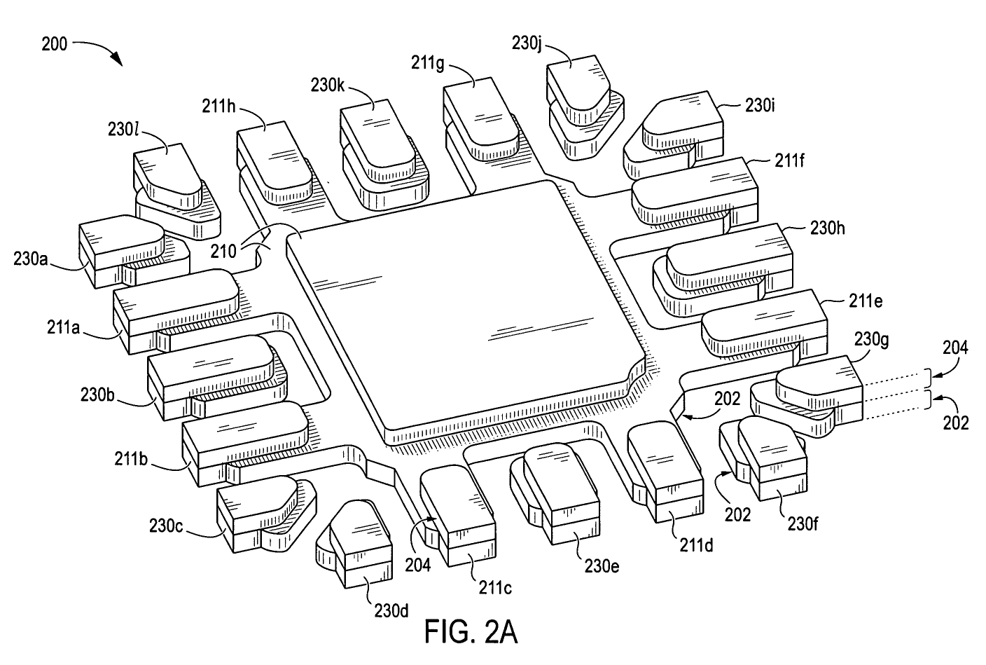

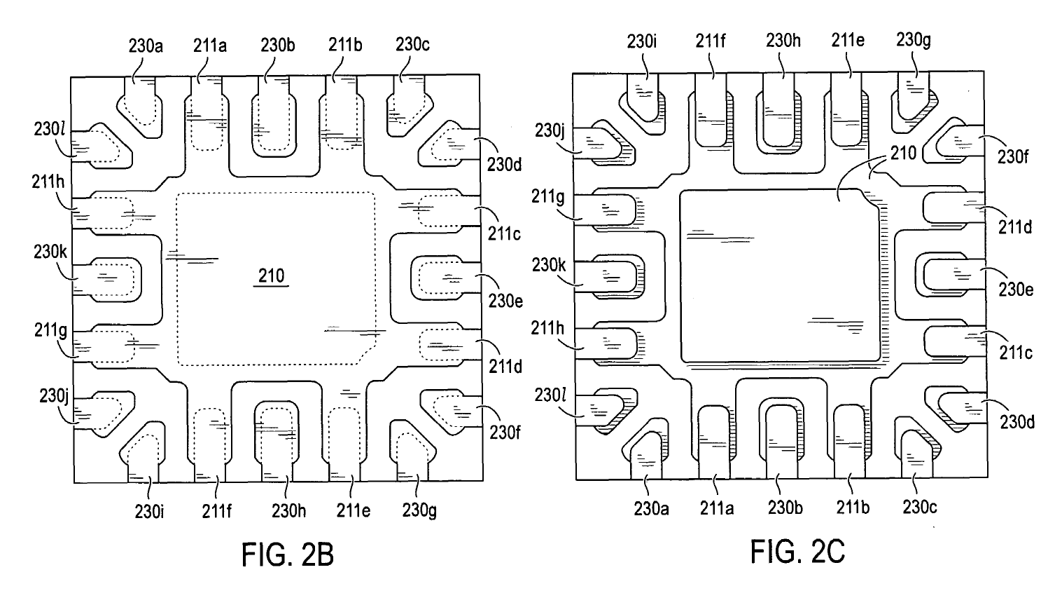

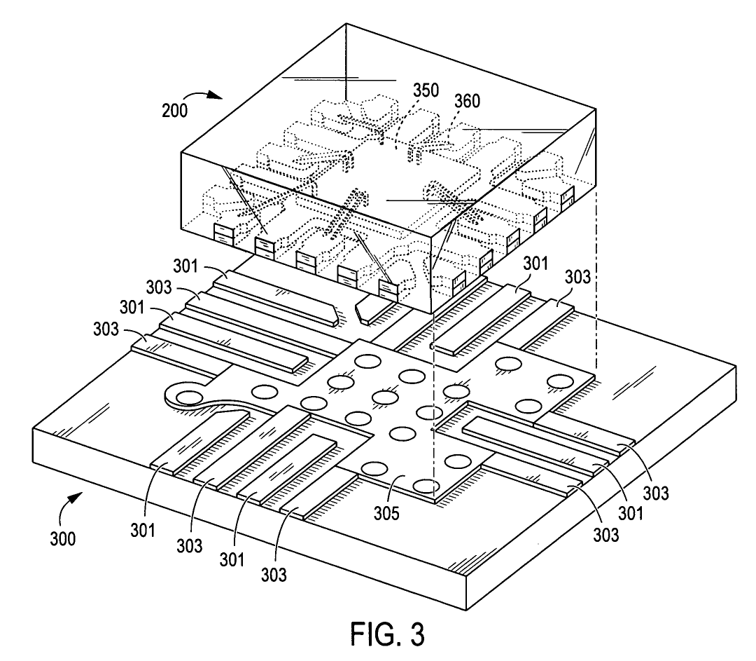

Referring now to FIG. 2A, a perspective bottom view of a lead frame package 200 in accordance with an exemplary embodiment of the present invention is provided. The lead frame package includes a top portion 202 and a bottom portion 204, each portion comprised of a conductive metal (e.g., copper). The lead frame package 200 also comprises a die attach pad 210, one or more tie bars 211a-h and one or more electrical interconnections 230a-l. As shown in FIG. 2A, the electrical interconnections 230a-l, die attach pad 210, and tie bars 211a-h in the bottom portion 204 of the lead frame package 200 are narrower than in the top portion 202. This feature provides the ability to better lock the position of the lead frame package 200 in plastic molding during manufacturing. The die attach pad 210 may be positioned generally at a center of the lead frame package 200. As will be recognized by those skilled in the art, the bottom portion 204 of the lead frame package 200 is attached to a circuit board assembly (shown in FIG. 3). Once the lead frame is affixed to the circuit board, a semiconductor die (element 350 illustrated in FIG. 3) may be attached to the top of the die attach pad 200 located on the upper portion of the lead frame package 200. The semiconductor die can then be connected to the electrical interconnections 230a-l via, for example, bonding wires (element 360 shown in FIG. 3).

Connected to the die attach pad 210 are one or more tie bars 211a-h. In the illustrated configuration shown in FIG. 2A, the lead frame package 200 comprises a total of 8 tie bars 211a-h. However, it should be understood that any desired number of tie bars may be utilized in accordance with embodiments of the present disclosure. Unlike conventional tie bars, the tie bars 211a-h of the present embodiment do not have to be attached to the corners of the die attach pad 210. FIGS. 2B and 2C illustrate top views and bottom views, respectively, of the lead frame assembly 200 depicted in FIG. 2A.

As shown in FIG. 2C, the exposed bottom portion surfaces of the tie-bars 211a-h are consistent (in size and shape) with the bottom portion surfaces of the electrical interconnections 230a-l. As a result, the bottom portion surfaces of the tie-bars 211a-h can be used as additional grounding. Furthermore, by configuring the tie bars 211a-h in this manner, the bottom portion 204 (i.e., the “footprint”) of the package 200 does not have to be altered in any way. As a result, conventional lead frame package manufacturing tools, equipment, and associated technology may be utilized to manufacture and test the novel lead frame packages according to embodiments of the present disclosure. It is important to note that conventional lead frame packages do not utilize tie bars in this manner, i.e., for further grounding a lead frame package. To the contrary, conventional lead frame packages are typically grounded using a direct connection between by a bottom portion of a die attach pad and a grounding contact on a mounting substrate. As further detailed below, using tie bars to provide additional grounding minimizes crosstalk and minimizes degradation of electrical performance of the lead frame package.

The exemplary lead-frame package 200 may comprise one or more non-tie bar electrical interconnections 230a-l. In one implementation, one or more of these interconnections 230a-l may comprise RF signal interconnections (230b, 230e, 230h, 230k), each of which is positioned between two or more of the tie bar interconnections 211a-h. As FIGS. 2A and 2B illustrate, RF signal interconnection 230b is positioned between ties bars 211a and 211b, RF signal interconnection 230e is positioned between ties bars 211c and 211d, RF signal interconnection 230h is positioned between ties bars 211e and 211f, and the RF signal interconnection 230k is positioned between ties bars 211g and 211h. As will be subsequently discussed, when grounded, the tie bars 211a-h provide an RF shield to the RF interconnections 230b, 230e, 230h, 230k, thereby preventing crosstalk between signals and eliminate package resonance.

Referring now to FIG. 3, an implementation of the exemplary lead frame package 200 of FIGS. 2A-2C and a circuit-board 300 is shown. It is noted that lead frame packages are generally employed in large circuits by mounting a desired number of lead frame packages on a circuit-board or other appropriate device. Similarly, the lead frame package 200 of FIG. 3 may be configured for use in larger circuits by mounting the package 200 on a circuit-board such as circuit board 300. For illustrative purposes, a semiconductor die 350 is shown employing wire-bonds 360 to six electrical interconnections.

The bottom portion 204 of lead frame package 200 may be mounted to the circuit-board 300, for example, using any appropriate means including soldering, to form an electrical connection between the electrical interconnections of the package 200 and the circuit-board 300. Further, the bottom portion 204 of the lead frame package 200 may be mounted onto the circuit-board 300 such that one or more signal interconnections 230a-l are electrically connected to one or more signal contacts 301 on the circuit board 300 and one or more tie bar interconnections 211a-h are electrically connected to the die attach pad 210 and/or grounding contacts 303 of the circuit-board 300. In this manner, the tie-bar interconnections 211a-h are connected to ground 305. Using the tie bars 211a-h in this manner serves a dual-purpose. First, any resonance of the tie bars 211a-h created by applying a signal to one or more of the electrical interconnections 230a-l may be minimized, if not eliminated altogether. This can be particularly beneficial when applying an RF signal above 10 GHz to one or more of the electrical interconnections 230a-l. Secondly, in the case where an RF signal interconnection 230b, 230e, 230h, 230k is positioned between two grounding ties bar interconnections (211a-h), the tie bars 211a-h provide an RF shield around the RF interconnections 230b, 230e, 230h, 230k, thereby preventing crosstalk.

It is noted that other interconnections 230a-l on the lead frame package 200 may be designated as desired, and then mounted such that the desired interconnections correspond between the package 200 and the circuit-board 300. The lead frame package 200 mounted on the circuit-board 300 may be referred to as a “mounted semiconductor circuit”.

In operation, an RF signal may be applied to a mounted semiconductor circuit via at least one RF signal interconnection. For instance, it may be assumed that the electrical interconnection 230b is an RF signal interconnection upon which an RF signal may be applied. In such a configuration, the RF signal interconnection 230b may be positioned between adjacent ties bars 211a and 211b, both of which are grounded. In conventional lead frame packages, RF signal interconnections are commonly located adjacent to other electrically conductive interconnections such as for example, other RF signal interconnections, IF signal interconnections, DC inputs, etc. As a result, signals from these interconnections may leak or cross over causing crosstalk between interconnections, thus corrupting the signal(s). However, in the current configuration, when an RF signal is applied to the RF signal interconnection 230b, the two adjacent grounded tie bars 211a, 211b function as an RF shield, thereby preventing crosstalk between adjacent interconnections. Since the grounded tie bars 211a, 211b are both non-conductive, they provide an electrical barrier for preventing signals from crossing over or leaking over.

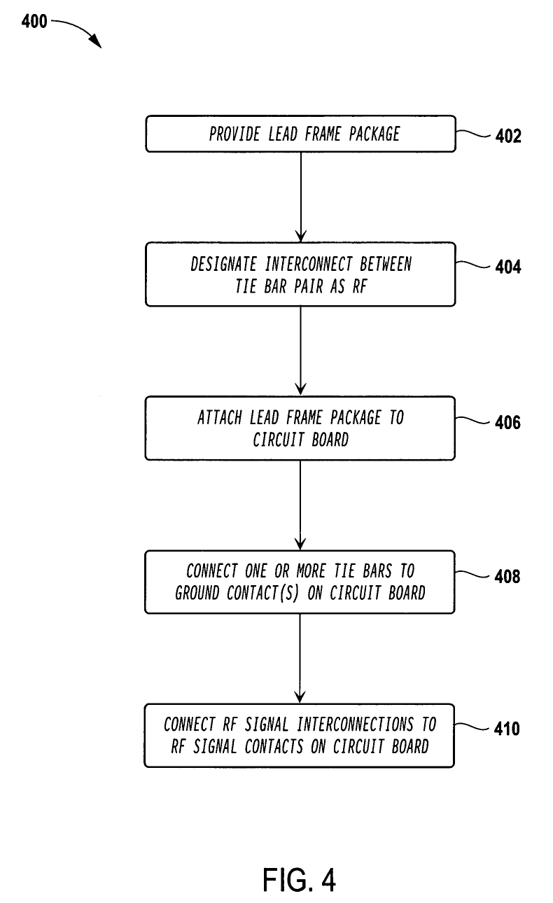

Referring now to FIG. 4, a flow diagram illustrating an exemplary method 400 in accordance with this disclosure. The method 400 begins at step 402, where a lead frame package comprising two or more electrical interconnections is provided. The lead frame package may be generally square-shaped comprising any number of electrical interconnections, each of which may be distributed about a periphery of the package.

The die attach pad 210 is affixed when the frame is created using any known etching process. The tie bars 211a-211h may provide additional ground, such that when the package is mounted to a circuit-board, the tie bars may be electrically connected to grounding contacts on the circuit board via the respective interconnections to which the ties bars are affixed. Further, the die attach pad 210 may be affixed multiple tie bars such that a pair of tie bars is positioned along either side of one of the remaining interconnections. An electrical interconnection positioned between two tie bars may then be designated as an RF signal interconnection (Step 404). As a result, when the lead frame package is mounted onto a circuit-board (next in step 406), the designated RF signal interconnection may be electrically connected to an RF signal contact on the circuit-board.

Next, in step 406, the lead frame package is mounted onto a circuit-board. The circuit-board may be any appropriate circuit-board, motherboard, device, and the like. The lead frame package may be mounted on the circuit-board using any appropriate means. In one embodiment, the package is mounted on the circuit-board using solder, thereby providing electrical connectivity between the package and the board.

When the lead frame package is mounted on the circuit-board (step 406) one or more the tie bars may be connected to grounding contacts on the circuit board via the electrical connections to which the tie bars are affixed (step 408). Grounding the tie bars in this manner serves a dual purpose. First, any resonance of the tie bars created by applying a signal, particularly an RF signal above 10 GHz, to one or more of the electrical interconnections may be minimized, if not eliminated altogether. Secondly, the tie bars provide an RF shield to signal interconnections, thereby preventing crosstalk between adjacent interconnections.

Also when the lead frame package is connected to the circuit board, the electrical interconnections designated as RF may be connected to RF contacts on the circuit-board (step 410). The remaining interconnections on the lead frame package may be designated as desired, and then connected to contacts on the circuit-board as appropriate.

Although the method and apparatus disclosed herein have been described in terms of exemplary embodiments, they is not limited thereto. Rather, the appended claims should be construed broadly to include other variants and embodiments of the disclosure which may be made by those skilled in the art without departing from the scope and range of equivalents of the disclosure.

What is claimed is:

1. A lead frame package comprising:
a die attach pad; and
two or more electrical interconnections, wherein at least one of the interconnections is affixed to the die attach pad for electrically grounding the lead frame package.

2. The lead frame package of claim 1, wherein at least one of the interconnections is a radio-frequency (RF) signal interconnection.

3. The lead frame package of claim 2, wherein at least one of the interconnections is affixed to the die attach pad via one or more ties bars.

4. The lead frame package of claim 1, comprising three or more electrical interconnections, wherein at least one of the interconnections is a signal interconnection and at least two other interconnections are grounding interconnections affixed to the die attach pad, the at least one signal interconnection being positioned between the at least two grounding interconnections.

5. The lead frame package of claim 4, wherein the at least one signal interconnection is an RF signal interconnection.

6. A method of manufacturing a lead frame package comprising:
providing a lead frame package, the lead frame package comprising two or more electrical interconnections and a die attach pad, wherein at least one electrical interconnection is affixed to the die attach pad to ground the lead frame package and wherein at least one of the electrical interconnections is an RF signal interconnection;
connecting at least one of the die attach pad and the at least one grounding electrical interconnection to a grounding contact of a circuit-board; and
connecting the at least one RF signal electrical interconnection to an RF signal contact on the circuit-board, thereby forming a mounted semi-conductor circuit.

7. The method of claim 6, wherein the die attach pad is affixed to the at least one electrical interconnection via one or more tie bars.

8. The method of claim 6, wherein the lead frame package comprises three or more electrical interconnections, at least two of which are affixed to the die attach pad via one or more tie bars.

9. The method of claim 8 wherein the at least one RF interconnection is positioned between at least two grounding electrical interconnections.

10. The method of claim 9, further comprising:
attaching the lead frame package to a circuit-board, such that the at least two grounding electrical interconnections are connected to grounding contacts on the circuit-board, and the at least one designated RF signal interconnections is connected to an RF signal contact on the circuit-board.
